(19) United States
(12) Patent Application Publication
(10) Pub. No.: US 2018/0350563 A1
(43) Pub. Date: Dec. 6, 2018

(54) QUALITY IMPROVEMENT OF FILMS DEPOSITED ON A SUBSTRATE

(71) Applicant: Applied Materials, Inc., Santa Clara, CA (US)

(72) Inventors: Pramit MANNA, Sunnyvale, CA (US); Abhijit Basu MALLICK, Fremont, CA (US); Kurtis LESCHKIES, San Jose, CA (US); Steven VERHAVERBEKE, San Francisco, CA (US); Sanjay KAMATH, Fremont, CA (US); Zongbin WANG, Singapore (SG); Hanwen ZHANG, Singapore (SG); Shishi JIANG, Santa Clara, CA (US)

(21) Appl. No.: 15/991,877

(22) Filed: May 29, 2018

Related U.S. Application Data
(60) Provisional application No. 62/514,545, filed on Jun. 2, 2017.

(51) Int. Cl. H01J 37/32

(52) U.S. Cl. CPC H01J 37/32522; H01J 37/32715; H01J 37/32816

(57) ABSTRACT

Embodiments of the disclosure generally relate to a method of processing a semiconductor substrate at a temperature less than 250 degrees Celsius. In one embodiment, the method includes loading the substrate with the deposited film into a pressure vessel, exposing the substrate to a processing gas comprising an oxidizer at a pressure greater than about 2 bars, and maintaining the pressure vessel at a temperature between a condensation point of the processing gas and about 250 degrees Celsius.

### CROSS-REFERENCE TO RELATED APPLICATIONS

This application claims benefit of U.S. provisional patent application Ser. No. 62/514,545, filed Jun. 2, 2017, which is herein incorporated by reference.

### BACKGROUND

### Field

Embodiments of the disclosure generally relate to fabrication of integrated circuits and particularly to a method of improving quality of a film deposited on a semiconductor substrate.

### Description of the Related Art

Formation of a semiconductor device, such as memory devices, logic devices, microprocessors, etc., involves deposition of a film over semiconductor substrates. The film is used to create the circuitry for manufacturing the device. Materials deposited using conventional methods and treated above 250 degrees Celsius can be damaged by the elevated temperatures. However, films formed within low thermals budget, such as below 250 degrees Celsius, often have poor quality due to higher porosity and lower density. These films are susceptible to faster etching due to such quality issues.

Thus, there is a need for a method of improving quality of a film deposited on a semiconductor substrate at a temperature less than 250 degrees Celsius.

### SUMMARY

Embodiments of the disclosure generally relate to a method of processing a substrate at a temperature less than 250 degrees Celsius. In one embodiment, the method includes loading the substrate with the deposited film into a pressure vessel, exposing the substrate to a processing gas comprising an oxidizer at a pressure greater than about 2 bars, and maintaining the pressure vessel at a temperature between a condensation point of the processing gas and about 250 degrees Celsius.

In another embodiment of the disclosure, the method includes loading a cassette with a plurality of substrates into a pressure vessel, each substrate having a film deposited thereon, exposing the plurality of substrates to a processing gas comprising an oxidizer at a pressure greater than about 2 bars, and maintaining the pressure vessel at a temperature between a condensation point of the processing gas and about 250 degrees Celsius.

In yet another embodiment of the disclosure, the method includes opening a first valve, flowing a processing gas comprising an oxidizer into a chamber having a substrate with a film disposed therein at a pressure greater than about 2 bars, exposing the processing gas to the substrate, wherein the processing gas is maintained above a condensation point temperature thereof and below a temperature of about 250 degrees Celsius, closing the first valve, and opening a second valve to remove the processing gas from the chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, as the disclosure may admit to other equally effective embodiments.

FIG. 1 is a simplified front cross-sectional view of a pressure vessel for improving quality of a film deposited on a substrate at a temperature less than 250 degrees Celsius.

FIG. 2A is a simplified cross-sectional view of a low-quality film deposited on a semiconductor substrate.

FIG. 2B is a simplified cross-sectional view of the film having an improved quality after performing the method described herein.

FIG. 3 is a block diagram of a method of improving quality of a film deposited on a semiconductor substrate at a temperature less than 250 degrees Celsius.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

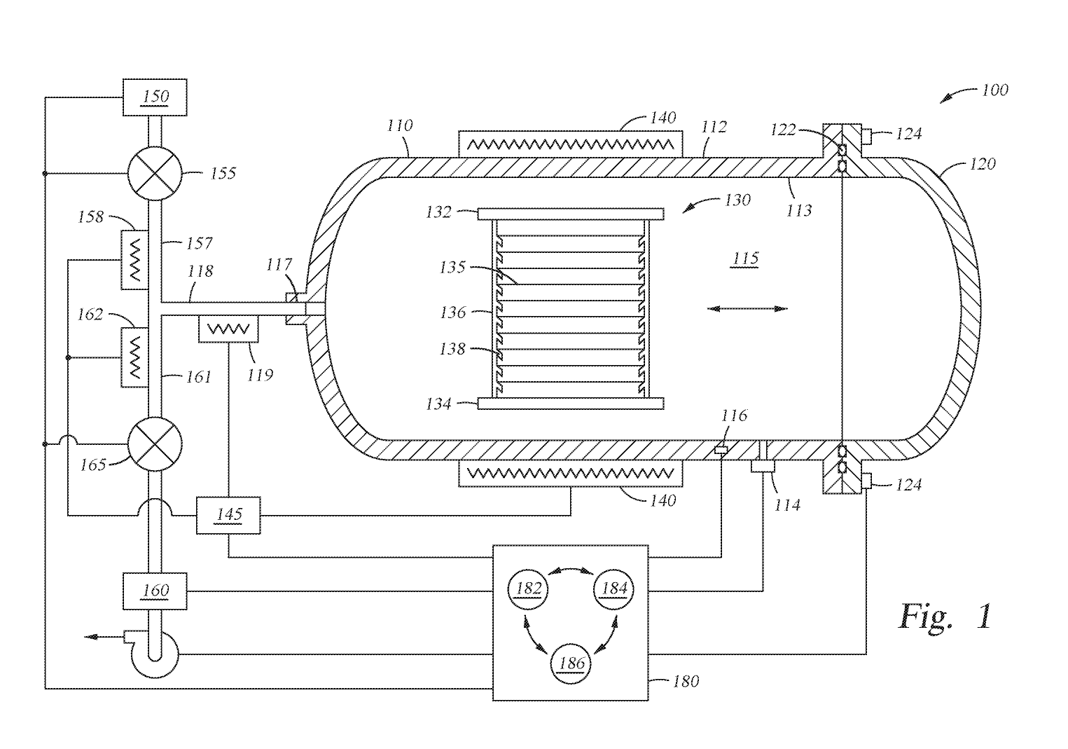

Embodiments of the disclosure generally relate to a method of improving quality of a film deposited on a semiconductor substrate at a temperature less than 250 degrees Celsius. The method heals regions of a poor-quality film deposited at a temperature less than 200 degrees Celsius. In some embodiments, the film is produced using the Producer® Avila™ plasma enhanced chemical vapor deposition chamber (PECVD) chamber, commercially available from Applied Materials, Inc., of Santa Clara, Calif. In other embodiments, the film may be produced by any chemical vapor deposition (CVD) or physical vapor deposition (PVD) technique, including in chambers produced by other manufacturers. The film is exposed to a processing gas including an oxidizer under high pressure during the post-deposition annealing process disclosed herein, to increase the density of the film. The processing gas penetrates deep into the film layer to reduce the porosity through an oxidation process, thus enhancing the density and the quality of the film deposited on the substrate. A batch processing chamber, such as but not limited to a pressure vessel 100 shown in FIG. 1 and described herein, is utilized for the purpose of performing the high-pressure annealing process. However, the method described herein can be equally applied to a single substrate disposed in a single substrate chamber.

FIG. 1 is simplified front cross-sectional view of a pressure vessel 100 for the high-pressure annealing process. The pressure vessel 100 has a body 110 with an outer surface 112 and an inner surface 113 that encloses a processing region 115. In some embodiments such as in FIG. 1, the body 110 has an annular cross section, though in other embodiments the cross-section of the body 110 may be rectangular or any closed shape. The outer surface 112 of the body 110 may be made from a corrosion resistant steel (CRS), such as but not limited to stainless steel. The inner surface 113 of the body 110 may be made from nickel-based steel alloys that exhibit high resistance to corrosion, such as but not limited to HASTELLOY®.

The pressure vessel 100 has a door 120 configured to sealably enclose the processing region 115 within the body 110 such that the processing region 115 can be accessed when the door 120 is open. A high-pressure seal 122 is utilized to seal the door 120 to the body 110 in order to seal the processing region 115 for processing. The high-pressure seal 122 may be made from a polymer, such as but not limited to a perflouroelastomer. A cooling channel 124 is disposed on the door 120 adjacent to the high-pressure seals 122 in order to maintain the high-pressure seals 122 below the maximum safe-operating temperature of the high-pressure seals 122 during processing. A cooling agent, such as but not limited to an inert, dielectric, and/or high-performance heat transfer fluid, may be circulated within the cooling channel 124 to maintain the high-pressure seals 122 at a temperature between about 150 degrees Celsius and 250 degrees Celsius. The flow of the cooling agent within the cooling channel 124 is controlled by a controller 180 through feedback received from a temperature sensor 116 or a flow sensor (not shown).

The pressure vessel 100 has a port 117 through the body 110. The port 117 has a pipe 118 therethrough, which is coupled to a heater 119. One end of the pipe 118 is connected to the processing region 115. The other end of the pipe 118 bifurcates into an inlet conduit 157 and an outlet conduit 161. The inlet conduit 157 is fluidly connected to a gas panel 150 via an isolation valve 155. The inlet conduit 157 is coupled to a heater 158. The outlet conduit 161 is fluidly connected to a condenser 160 via an isolation valve 165. The outlet conduit 161 is coupled to a heater 162. The heaters 119, 158, and 162 are configured to maintain a processing gas flowing through the pipe 118, inlet conduit 157, and the outlet conduit 161 respectively at a temperature between the condensation point of the processing gas and about 250 degrees Celsius. The heaters 119, 158, and 162 are powered by a power source 145.

The gas panel 150 is configured to provide a processing gas including an oxidizer under pressure into the inlet conduit 157 for transmission into the processing region 115 through the pipe 118. The pressure of the processing gas introduced into the processing region 115 is monitored by a pressure sensor 114 coupled to the body 110. The condenser 160 is fluidly coupled to a cooling fluid and configured to condense a gaseous product flowing through the outlet conduit 161 after removal from the processing region 115 through the pipe 118. The condenser 160 converts the gaseous products from the gas phase into liquid phase. A pump 170 is fluidly connected to the condenser 160 and pumps out the liquefied products from the condenser 160. The operation of the gas panel 150, the condenser 160, and the pump 170 are controlled by the controller 180.

The isolation valves 155 and 165 are configured to allow only one fluid to flow through the pipe 118 into the processing region 115 at a time. When the isolation valve 155 is open, the isolation valve 165 is closed such that a processing gas flowing through inlet conduit 157 enters into the processing region 115, preventing the flow of the processing gas into the condenser 160. On the other hand, when the isolation valve 165 is open, the isolation valve 155 is closed such that a gaseous product is removed from the processing region 115 and flows through the outlet conduit 161, preventing the flow of the gaseous product into the gas panel 150.

One or more heaters 140 are disposed on the body 110 and configured to heat the processing region 115 within the pressure vessel 100. In some embodiments, the heaters 140 are disposed on an outer surface 112 of the body 110 as shown in FIG. 1, though in other embodiments, the heaters 140 may be disposed on an inner surface 113 of the body 110. Each of the heaters 140 may be a resistive coil, a lamp, a ceramic heater, a graphite-based carbon fiber composite (CFC) heater, a stainless steel heater, or an aluminum heater, among others. The heaters 140 are powered by the power source 145. Power to the heaters 140 is controlled by a controller 180 through feedback received from a temperature sensor 116. The temperature sensor 116 is coupled to the body 110 and monitors the temperature of the processing region 115.

A cassette 130, coupled to an actuator (not shown), is moved in and out of the processing region 115. The cassette 130 has a top surface 132, a bottom surface 134, and a wall 136. The wall 136 of the cassette 130 has a plurality of substrate storage slots 138. Each substrate storage slot 138 is evenly spaced along the wall 136 of the cassette 130. Each substrate storage slot 138 is configured to hold a substrate 135 therein. The cassette 130 may have as many as fifty substrate storage slots 138 for holding the substrates 135. The cassette 130 provides an effective vehicle both for transferring a plurality of substrates 135 into and out of the pressure vessel 100 and for processing the plurality of substrates 135 in the processing region 115.

The controller 180 controls the operation of the pressure vessel 100. The controller 180 controls the operation of the gas panel 150, the condenser 160, the pump 170, the isolation valves 155 and 165, as well as the power source 145. The controller 180 is also communicatively connected to the temperature sensor 116, the pressure sensor 114, and the cooling channel 124. The controller 180 includes a central processing unit (CPU) 182, a memory 184, and a support circuit 186. The CPU 182 may be any form of a general purpose computer processor that may be used in an industrial setting. The memory 184 may be a random access memory, a read-only memory, a floppy, or a hard disk drive, or other form of digital storage. The support circuit 186 is conventionally coupled to the CPU 182 and may include cache, clock circuits, input/output systems, power supplies, and the like.

The pressure vessel 100 provides a convenient chamber to perform the method of improving quality of a film deposited on a plurality of substrates 135 at a temperature less than 250 degrees Celsius. During operation, the heaters 140 are powered on to pre-heat the pressure vessel 100 and maintain the processing region 115 at a temperature less than 250 degrees Celsius. At the same time, the heaters 119, 158, and 162 are powered on to pre-heat the pipe 118, the inlet conduit 157, and the outlet conduit 161, respectively.

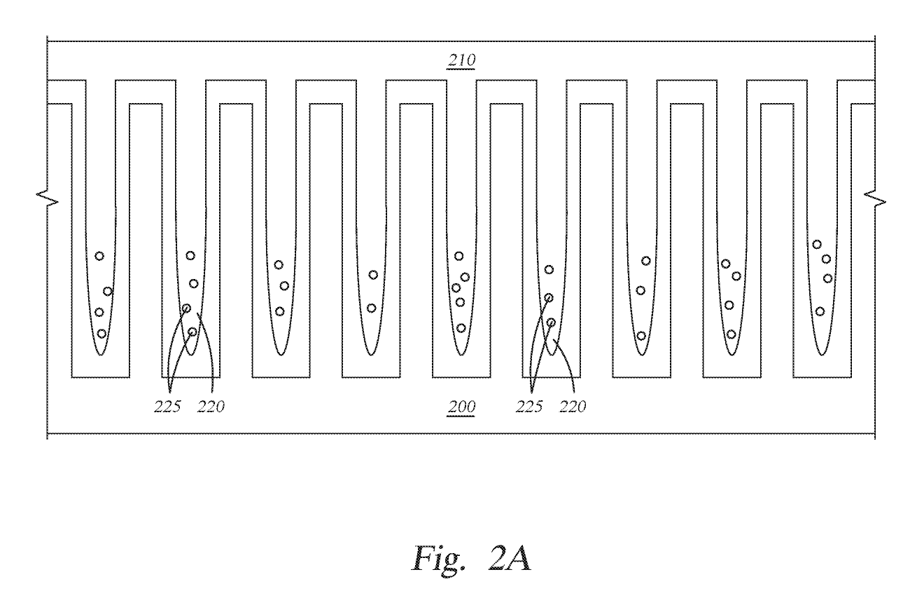

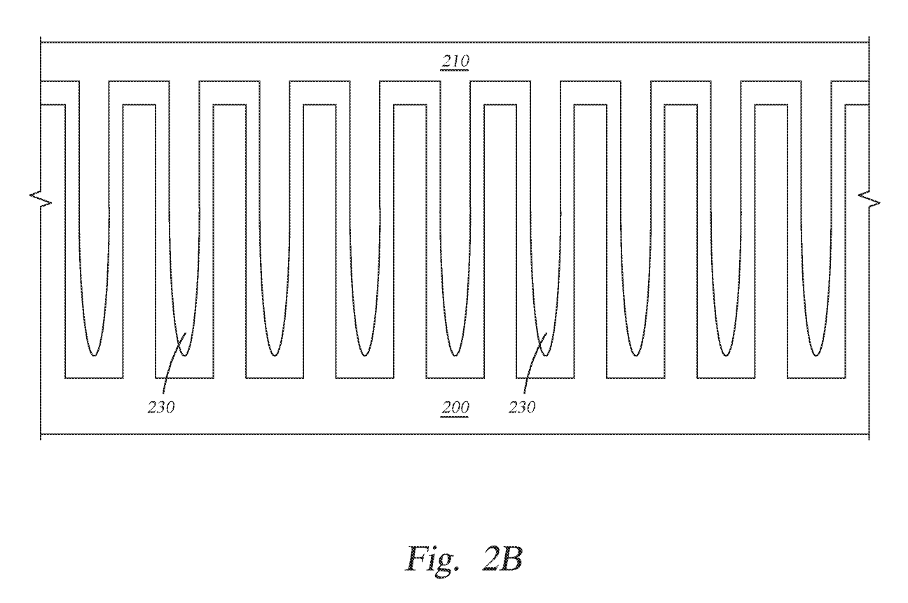

The plurality of substrates 135 are loaded on the cassette 130. Each of the substrates 135 are observed as the semiconductor substrate 200 in FIG. 2A when the substrates 135 are loaded on the cassette 130. FIG. 2A shows a simplified cross-sectional view of a low-quality film deposited on a semiconductor substrate 200, similar to the substrates 135, before the substrates 135 are loaded on the cassette 130. The substrate 200 has a film 210 deposited thereon at a temperature less than 200 degrees Celsius. In some embodiments, the film 210 may also include a silicon oxide, a silicon nitride, or a silicon oxynitride. In other embodiments, the film 210 may also include a metallic oxide, a metallic nitride, or a metallic oxynitride. The quality of the film 210 is low due to the presence of a plurality of pores 225 within the trenches 220 of the film 210. The pores 225 are open spaces located deep within the trenches 220 of the film 210 and result in the film 210 having a low density.

The door 120 of the pressure vessel 100 is opened to move the cassette 130 into the processing region 115. The door 120 is then sealably closed to provide a high-pressure chamber within the pressure vessel 100. The seals 122 ensure that there is no leakage of pressure from the processing region 115 once the door 120 is closed.

A processing gas is provided by the gas panel 150 into the processing region 115 inside the pressure vessel 100. The isolation valve 155 is opened by the controller 180 to allow the processing gas to flow through the inlet conduit 157 and the pipe 118 into the processing region 115. The processing gas is introduced at a flow rate of between about 500 sccm and about 2000 sccm for a period of between about 1 minute and about 10 minutes. The isolation valve 165 is kept closed at this time. The processing gas is an oxidizer flowed into processing region 115 under high pressure. The pressure at which the processing gas is applied is increased incrementally. The oxidizer effectively drives the film 210 into a more complete oxidation state, particularly in the deeper portions of the trenches 220. In the embodiment described herein, the processing gas is steam under a pressure between about 5 bars and about 35 bars. However, in other embodiments, other oxidizers, such as but not limited to ozone, oxygen, a peroxide or a hydroxide-containing compound may be used. The isolation valve 155 is closed by the controller 180 when sufficient steam has been released by the gas panel 150.

During processing of the substrates 135, the processing region 115 as well as the inlet conduit 157, the outlet conduit 161 and the pipe 118 are maintained at a temperature and pressure such that the processing gas stays in gaseous phase. The temperatures of the processing region 115 as well as the inlet conduit 157, the outlet conduit 161 and the pipe 118 are maintained at a temperature greater than the condensation point of the processing gas at the applied pressure but less than 250 degrees Celsius. The processing region 115, as well as the inlet conduit 157, the outlet conduit 161, and the pipe 118, are maintained at a pressure less than the condensation pressure of the processing gas at the applied temperature. The processing gas is selected accordingly. In the embodiment described herein, steam under a pressure of between about 5 bars and about 35 bars is an effective processing gas when the pressure vessel is maintained at a temperature between about 150 degrees Celsius and about 250 degrees Celsius. This ensures that the steam does not condense into water, which may harm the film 210 deposited on the substrate 200.

The processing is complete when the film is observed to have the desired density, as verified by testing the wet etch rate of the film and electrical leakage and breakdown characteristics. The isolation valve 165 is then opened to flow the processing gas from the processing region 115 through the pipe 118 and outlet conduit 161 into the condenser 160. The processing gas is condensed into liquid phase in the condenser 160. The liquefied processing gas is then removed by the pump 170. When the liquefied processing gas is completely removed, the isolation valve 165 closes. The heaters 140, 119, 158, and 162 are then powered off. The door 120 of the pressure vessel 100 is then opened to remove the cassette 130 from the processing region 115. Each of the substrates 135 are observed as the semiconductor substrate 200 in FIG. 2B, when the substrates 135 are unloaded from the cassette 130. FIG. 2B is a simplified cross-sectional view of a high-quality film 210 deposited on the substrate 200. The trenches 230 of the high-quality film 210 have no pores and as a result, the film 210 has low porosity and high density.

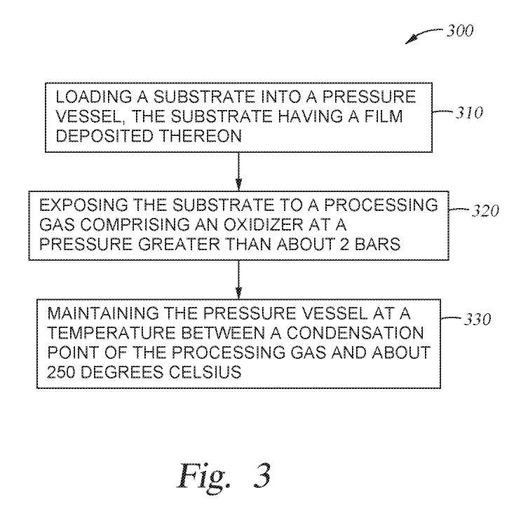

FIG. 3 is a block diagram of a method of improving quality of a film deposited on a semiconductor substrate at a temperature less than 250 degrees Celsius, according to one embodiment of the present disclosure. The method 300 begins at block 310 by loading a substrate or a plurality of substrates on a cassette into a pressure vessel. In some embodiments, the substrate has a film of a silicon oxide, a silicon nitride, or a silicon oxynitride deposited thereon. In other embodiments, the substrate has a film of a metallic oxide, a metallic nitride, or a metallic oxynitride deposited thereon. In some embodiments, a plurality of substrates may be placed on a cassette and loaded into the pressure vessel. In other embodiments, a cassette may be omitted.

At block 320, the substrate or the plurality of substrates are exposed to a processing gas including an oxidizer at a pressure greater than about 2 bars. In some embodiments, the processing gas is an oxidizer including one or more of ozone, oxygen, water vapor, heavy water, a peroxide, a hydroxide-containing compound, oxygen isotopes (14, 15, 16, 17, 18, etc.) and hydrogen isotopes (1, 2, 3), or some combination thereof. The peroxide may be hydrogen peroxide in gaseous phase. In some embodiments, the oxidizer comprises a hydroxide ion, such as but not limited to water vapor or heavy water in vapor form. In some embodiments, the substrate or the plurality of substrates are exposed to steam at a pressure between about 5 bars to about 35 bars, where the pressure is incrementally increased from about 5 bars to about 35 bars. In some embodiments, the steam is introduced at a flow rate of about 500 sccm for a period of about 1 minute.

At block 330, the pressure vessel is maintained at a temperature between a condensation point of the processing gas and about 250 degrees Celsius, while the substrate with the film thereon is exposed to the processing gas. In the embodiments where steam at a pressure between about 5 bars to about 35 bars is used, the temperature of the pressure vessel is maintained between about 150 degrees Celsius and about 250 degrees Celsius.

Application of a processing gas containing an oxidizer under high pressure allows a high concentration of the oxidizing species from the processing gas to infiltrate deeply into the trenches of the film such that the oxidizing species can more thoroughly oxidize the film. The high pressure inside the pressure vessel drives the diffusion of the oxidizing species into the deeper trenches, where the more porous regions are located. The quality of the processed film formed can be verified by a reduction in wet etch rate of the film by about two-third, as compared to the quality of the film before the process. The quality of the processed film can also be verified by testing electrical properties such as breakdown voltage, leakage current, etc. For a process performed at a relatively low temperature of less than 250 degrees Celsius, the achievement in film quality improvement is substantially similar to a process performed at 500 degrees Celsius at atmospheric pressure. Moreover, the time required to complete the high-pressure steam annealing of the film between about 150 degrees Celsius and about 250 degrees Celsius is about 30 minutes, which makes the process relatively faster than a conventional steam annealing process performed at 500 degrees Celsius under atmospheric pressure.

The application of the processing gas at high pressure offers an advantage over the conventional steam annealing process at atmospheric pressure. A conventional steam annealing process at atmospheric pressure is inadequate due to poor diffusion and penetration depth of the oxidizing species into the film. The conventional steam annealing process generally does not drive the oxidizing species deeply into the film layer. As a result, the disclosure herein advantageously demonstrates an effective method of producing high-quality films deposited on a semiconductor substrate at a temperature less than 250 degrees Celsius. By producing high-quality films within the thermal budget, the method enables the creation of circuitry on the film to manufacture next-generation semiconductor devices of desirable applications.

While the foregoing is directed to particular embodiments of the present disclosure, it is to be understood that these embodiments are merely illustrative of the principles and applications of the present invention. It is therefore to be understood that numerous modifications may be made to the illustrative embodiments to arrive at other embodiments without departing from the spirit and scope of the present inventions, as defined by the appended claims.

What is claimed is:

1. A method of processing a substrate, comprising:
loading the substrate into a pressure vessel, the substrate having a film deposited thereon;
exposing the substrate to a processing gas comprising an oxidizer at a pressure greater than about 2 bars; and
maintaining the pressure vessel at a temperature between a condensation point of the processing gas and about 250 degrees Celsius.

2. The method of claim 1, wherein the film comprises one or more of:
a metallic oxide, a metallic nitride, or a metallic oxynitride.

3. The method of claim 1, wherein the film comprises one or more of:
a silicon oxide, a silicon nitride, or a silicon oxynitride.

4. The method of claim 1, wherein the oxidizer is selected from a group consisting of ozone, oxygen, water vapor, heavy water, a peroxide, a hydroxide-containing compound, oxygen isotopes and hydrogen isotopes.

5. The method of claim 1, wherein the oxidizer comprises a hydroxide ion.

6. The method of claim 1, wherein the oxidizer is a peroxide.

7. The method of claim 1, wherein exposing the substrate to a processing gas comprises:
exposing the substrate to steam at a pressure between about 5 bars to about 35 bars.

8. The method of claim 7, wherein the temperature of the pressure vessel is maintained between about 150 degrees Celsius and about 250 degrees Celsius during the exposing.

9. A method of processing substrates, the method comprising:
loading a cassette with a plurality of substrates into a pressure vessel, each substrate having a film deposited thereon;
exposing the plurality of substrates to a processing gas comprising an oxidizer at a pressure greater than about 2 bars; and
maintaining the pressure vessel at a temperature between a condensation point of the processing gas and about 250 degrees Celsius.

10. The method of claim 9, wherein the film comprises one or more of:
a metallic oxide, a metallic nitride, or a metallic oxynitride.

11. The method of claim 9, wherein the film comprises one or more of:
a silicon oxide, a silicon nitride, or a silicon oxynitride.

12. The method of claim 9, wherein the oxidizer is selected from a group consisting of ozone, oxygen, water vapor, heavy water, a peroxide, a hydroxide-containing compound, oxygen isotopes and hydrogen isotopes.

13. The method of claim 9, wherein the oxidizer comprises a hydroxide ion.

14. The method of claim 9, wherein the oxidizer is a peroxide.

15. The method of claim 9, wherein exposing the plurality of substrates to a processing gas comprises:
exposing the plurality of substrates to steam at a pressure between about 5 bars to about 35 bars.

16. The method of claim 15, wherein the temperature of the pressure vessel is maintained between about 150 degrees Celsius and about 250 degrees Celsius.

17. A method of treating a substrate sequentially comprising:
opening a first valve;
flowing a processing gas comprising an oxidizer into a chamber having a substrate with a film disposed therein at a pressure greater than about 2 bars;
exposing the processing gas to the substrate, wherein the processing gas is maintained above a condensation point temperature thereof and below a temperature of about 250 degrees Celsius;
closing the first valve; and
opening a second valve to remove the processing gas from the chamber.

18. The method of claim 18, wherein the film comprises one or more of:
a metallic oxide, a metallic nitride, or a metallic oxynitride.

19. The method of claim 18, wherein the film comprises one or more of:
a silicon oxide, a silicon nitride, or a silicon oxynitride.

20. The method of claim 18, wherein the oxidizer is selected from a group consisting of ozone, oxygen, water vapor, heavy water, a peroxide, a hydroxide-containing compound, oxygen isotopes and hydrogen isotopes.
